(19) United States
(12) Patent Application Publication
(10) Pub. No.: US 2024/0341111 A1
(43) Pub. Date: Oct. 10, 2024

(54) SYSTEMS AND METHODS FOR ELECTROLUMINESCENT DEVICES INCLUDING QUANTUM SHELLS EMBEDDED IN A PEROVSKITE HOST

(71) Applicant: BOARD OF REGENTS, THE UNIVERSITY OF TEXAS SYSTEM, Austin, TX (US)

(72) Inventors: Jason D. Slinker, Allen, TX (US); Aditya Kumar Mishra, Hillsboro, OR (US); Anton V. Malko, McKinney, TX (US)

(73) Assignee: BOARD OF REGENTS, THE UNIVERSITY OF TEXAS SYSTEM, Austin, TX (US)

(21) Appl. No.: 18/632,223

(22) Filed: Apr. 10, 2024

Related U.S. Application Data
(60) Provisional application No. 63/495,248, filed on Apr. 10, 2023.

(51) Int. Cl. H10K 50/11

(52) U.S. Cl. CPC H10K 50/11

(57) ABSTRACT

Systems and methods for an active emissive layer configured for use in an electroluminescent device. The active emissive layer includes a host-guest blend in which the host includes a perovskite (e.g., CsPbBr₃, CsPbCl₃, and/or CsPbI₃) and the guest includes quantum shells (QSs) embedded in the host. The QSs include a quantum-confined, spheroidal shell that is a first semiconductor (e.g., CdSe) sandwiched between a core and an outer layer that are a wider band gap semiconductor (e.g., CdS). The active emissive layer is formed by mixing a perovskite solution with a colloid to generate a blended mixture, where the colloid is the QSs suspended in a same solvent used for the perovskite solution. The perovskite solution is coated on a substrate to form a film that is then annealed, and electrodes are formed to flow a current through the active emissive layer, causing emitted light.

### CROSS-REFERENCE TO RELATED APPLICATION

This application claims priority to U.S. Provisional Patent Application Ser. No. 63/495,248 filed Apr. 10, 2023, and titled “QD-3D PEROVSKITE LIGHT-EMITTING ELECTROCHEMICAL CELL,” the entirety of which is incorporated herein by reference.

### ACKNOWLEDGEMENT OF GOVERNMENT SUPPORT

This invention was made with government support under grant number ECCS1906505 awarded by the National Science Foundation, and grant no. DE-SC0010697 awarded by the Department of Energy. The government has certain rights in the invention.

### BACKGROUND

### 1. Field

The present disclosure relates generally to systems and methods for active emissive layers in electroluminescent devices, and more particularly relates to light-emitting devices in which a light-emitting electrochemical cell includes the active emissive layer, and the active emissive layer has quantum shells within a perovskite host.

### 2. Discussion of Related Art

Quasi-two-dimensional (2D) II-VI colloidal semiconductor quantum wells (CQW) can be used as nanostructured semiconductors for optically or electrically pumped lasers, light emitting diodes (LEDs), and various types of photovoltaics sensitizers. Flat CQW, also known as semiconductor nanoplatelets (NPLs), benefit from large oscillator strengths, tunable bandgap, narrow emission linewidths, and high carrier mobilities. Unlike 0 D quantum dots (QDs), NPLs have strong quantum confinement only in one dimension with a much weaker in-plane confinement, which significantly alters their excitonic properties. While their superb single exciton (X) properties are now being widely exploited, the recombination pathways of multiexcitonic states (MX) are still under scrutiny. Strongly confined excitons experience fast non-radiative Auger recombination owning to enhanced Coulombic interactions and relaxation of the momentum conservation requirement. In contrast to many 0 D systems, however, Auger decay rates in NPLs are lower than in QDs, and it has been demonstrated that biexciton quantum yield (QY^{BX}) can approach that of a single exciton state.

The flat geometry of colloidal NPLs brings about its own challenges. Their giant oscillator strength corresponding to coherent exciton motion results in fast radiative decay rates preferable for single exciton applications (i.e., LEDs and single photon sources). However, the concurrent fast relaxation of multiexcitons poses challenges to the lasing applications that would benefit from much longer gain lifetimes for both optical and electrical injection as the threshold of the later process is inversely proportional to the BX lifetime. While still elusive, developing electrical injection strategies for colloidal nanocrystal lasers is desired, in view of the broad scope of applications in optoelectronic concepts.

It is with these observations in mind, among others, that various aspects of the present disclosure were conceived and developed.

### BRIEF SUMMARY

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

In some aspects, the techniques described herein relate to an active emissive layer configured for use in an electroluminescent device light-emitting electrochemical cell, the active emissive layer including: a host-guest blend having: a host with a perovskite, and a guest with quantum shells embedded in the host.

In some aspects, the techniques described herein relate to an active emissive layer, wherein the electroluminescent device is a light-emitting electrochemical cell.

In some aspects, the techniques described herein relate to an active emissive layer, wherein, the host-guest blend includes colloidal nanocrystals.

In some aspects, the techniques described herein relate to an active emissive layer, wherein, the host is soluble in a same solvent that is used as a solution of the guest.

In some aspects, the techniques described herein relate to an active emissive layer, wherein, the quantum shells include a quantum-confined, spheroidal shell having a first semiconductor that is sandwiched between a core and an outer layer, the core and the outer layer including a second semiconductor having a wider band gap than the first semiconductor.

In some aspects, the techniques described herein relate to an active emissive layer, wherein, the quantum shells are sized to suppress multi-exciton Auger recombination.

In some aspects, the techniques described herein relate to an active emissive layer, wherein, the first semiconductor is formed of a first material, the first material is CdSe, the core includes a second semiconductor formed of a second material, the second material is CdS, and the outer layer includes the second semiconductor.

In some aspects, the techniques described herein relate to an active emissive layer, wherein, the cores of the quantum shells have a diameter that is in a range of about 4 nanometers to about 10 nanometers.

In some aspects, the techniques described herein relate to an active emissive layer, wherein, the host is operable to emit light in a first wavelength range when an electrical current is applied through the host, and the guest is operable to emit light in a second wavelength range when the electrical current is applied through the guest.

In some aspects, the techniques described herein relate to an active emissive layer, wherein, the first wavelength range depends on a counterion of the perovskite, and the second wavelength range depends on (i) dimensions of a quantum well in the quantum shells, and (ii) a semiconductor material of the quantum well.

In some aspects, the techniques described herein relate to an active emissive layer, wherein, a mass ratio of the quantum shells to the perovskite is in a range of about 5% to about 15%.

In some aspects, the techniques described herein relate to an active emissive layer, wherein, the perovskite has a molecular structure that includes a monovalent cation labeled “A”, a divalent cation labeled “B”, and a monovalent anion labeled “X”; and the molecular structure is represented by ABX3.

In some aspects, the techniques described herein relate to an active emissive layer, wherein, the perovskite is CsPbCl₃ or CsPbI₃.

In some aspects, the techniques described herein relate to an active emissive layer, wherein, the perovskite is CsPbBr₃.

In some aspects, the techniques described herein relate to an active emissive layer, wherein, the active emissive layer is operable to tune an apparent color of light emitted from the active emissive layer by changing a current to flow through the active emissive layer and/or by changing of voltage applied across the active emissive layer that causes a current to flow through the active emissive layer.

In some aspects, the techniques described herein relate to an active emissive layer, wherein, the quantum shells include first shells having first quantum wells of a first diameter, the first quantum wells include quantum-confined, spheroidal shell, the quantum shells include second shells having second quantum wells of a second diameter that is larger than the first diameter, and the first shells are operable to emit light in a different wavelength range than the second shells.

In some aspects, the techniques described herein relate to a method to fabricate an active emissive layer configured for use in a light-emitting electrochemical cell (LEC), the method including: preparing a solution with a perovskite in a first solvent; preparing a colloid with quantum shells suspended in a second solvent, the second solvent and the first solvent being a same solvent; mixing the perovskite solution with the colloid to generate a blended mixture; providing the active emissive layer of the mixture on a substrate, and removing the first solvent to solidify the active emissive layer, the conductive surface being on a first side of the active emissive layer.

In some aspects, the techniques described herein relate to a method, wherein, the substrate has a conductive surface including a first electrode and a second electrode, and the method further includes applying a voltage between the first electrode and the second electrode thereby causing a current through the active emissive layer, and the current causes light to be emitted from the active emissive layer.

In some aspects, the techniques described herein relate to a method, further including providing a conductor on a second side of the active emissive layer, wherein the substrate has a conductive surface.

In some aspects, the techniques described herein relate to a method, further including applying a voltage between the conductive surface conductor on the second side causing a current through the active emissive layer, the current causing light to be emitted from the active emissive layer.

In some aspects, the techniques described herein relate to a method, wherein, the providing of the active emissive layer of the mixture on the substrate includes: spin coating the mixture on the substrate to form a film having a thickness in a range of about 40 nanometers to about 400 nanometers, and annealing the film at a temperature in a range of about 130° C. to about 170° C. for a period of about 10 minutes to about 30 minutes to form the active emissive layer.

In some aspects, the techniques described herein relate to a method, wherein, the preparing of the solution with the perovskite in the first solvent includes dissolving PbBr2 and CsBr in a dimethyl sulfoxide (DMSO) to generate the solution, the solution includes a polyelectrolyte and LiPF6, the preparing of the colloid includes suspending the quantum shells in the DMSO solvent, and the quantum shells include spheroidal shell with CdSe sandwiched between a core and an outer layer respectively including CdS.

In some aspects, the techniques described herein relate to a method, wherein, the polyelectrolyte includes polyethylene oxide (PEO), the solution is prepared such that CsPbBr₃, PEO, and LiPF6 are mixed in about a 100:80:0.5 weight ratio, and the blended mixture has a weight ratio for QS:QS+CsPbBr₃ in a range of about 5 wt % to about 15 wt %.

### BRIEF DESCRIPTION OF THE DRAWINGS

The foregoing summary, as well as the following detailed description, will be better understood when read in conjunction with the appended drawings. For the purpose of illustration, there is shown in the drawings certain embodiments of the disclosed subject matter. It should be understood, however, that the disclosed subject matter is not limited to the precise embodiments and features shown. The accompanying drawings, which are incorporated in and constitute a part of this specification, illustrate an implementation of systems and methods consistent with the disclosed subject matter and, together with the description, serves to explain advantages and principles consistent with the disclosed subject matter, in which:

FIG. 1A illustrates an example of a host-guest active emissive layer, according to certain implementations.

FIG. 1B illustrates an example of a quantum shell (QS), according to certain implementations.

FIG. 2 illustrates an example of an electroluminescence spectrum from a QS-perovskite (QS-Pe) blend, according to certain implementations.

FIG. 3 illustrates an example of a system for producing the active emissive layer, according to certain implementations.

FIG. 4A illustrates an example of a plot of measured data representing the current through the active emissive layer as a function of the voltage applied across the active emissive layer, according to certain implementations.

FIG. 4B illustrates an example of a plot of measured data representing the radiant exitance from the active emissive layer as a function of the voltage applied across the active emissive layer, according to certain implementations.

FIG. 4C illustrates an example of a plot of measured data representing external quantum efficiency (EQE) for lighted emitted from the active emissive layer as a function of the voltage applied across the active emissive layer, according to certain implementations.

FIG. 5 illustrates a flow diagram of an example of a method for producing the active emissive layer, according to certain implementations.

FIG. 6A illustrates an example of a Transmission Electron Microscope (TEM) image of small core (e.g., about 4.5 nm diameter) QSs, according to certain implementations.

FIG. 6B illustrates an example of a TEM image of medium core (e.g., about 6 nm diameter) QSs, according to certain implementations.

FIG. 6C illustrates an example of a TEM image of large core (e.g., about 8 nm diameter) QSs, according to certain implementations.

FIG. 7A illustrates an example of a plot of absorption and photoluminescence (PL) spectra for small core QSs, according to certain implementations.

FIG. 7B illustrates an example of a plot of absorption and PL spectra for medium core QSs, according to certain implementations.

FIG. 7C illustrates an example of a plot of absorption and PL spectra for large core QSs, according to certain implementations.

FIG. 8 illustrates an example of a plot of a blinking trace of a large core QS, according to certain implementations.

FIG. 9 illustrates an example of an expanded view of a plot of the blinking trace with discrete X; X⁻; and X⁺ intensity levels, according to certain implementations.

FIG. 10 illustrates an example of an expanded view of a plot of extracted lifetimes from the discrete X; X⁻; and X⁺ intensity levels, according to certain implementations.

FIG. 11 illustrates an example of an expanded view of a plot of gated antibunching traces at different gate values for the time gate (TG), according to certain implementations.

FIG. 12 illustrates an example of an expanded view of a plot of the gate delay dependent (TG) values of correlation function g²(0), according to certain implementations.

FIG. 13A illustrates an example of a plot of the correlation function g²(τ) for a small core QS in the first quartiles of AB values, according to certain implementations.

FIG. 13B illustrates an example of a plot of the correlation function g²(τ) for a small core QS in the median quartiles of AB values, according to certain implementations.

FIG. 13C illustrates an example of a plot of the correlation function g²(τ) for a small core QS in the third quartiles of AB values, according to certain implementations.

FIG. 14A illustrates an example of a plot of the correlation function g²(τ) for a medium core QS in the first quartiles of AB values, according to certain implementations.

FIG. 14B illustrates an example of a plot of the correlation function g²(τ) for a medium core QS in the median quartiles of AB values, according to certain implementations.

FIG. 14C illustrates an example of a plot of the correlation function g²(τ) for a medium core QS in the third quartiles of AB values, according to certain implementations.

FIG. 15A illustrates an example of a plot of the correlation function g²(τ) for a large core QS in the first quartiles of AB values, according to certain implementations.

FIG. 15B illustrates an example of a plot of the correlation function g²(τ) for a large core QS in the median quartiles of AB values, according to certain implementations.

FIG. 15C illustrates an example of a plot of the correlation function g²(τ) for a large core QS in the third quartiles of AB values, according to certain implementations.

FIG. 16A illustrates an example of a plot of the statistics of g²(0) values for all QSs (i.e., small, medium, and large cores), according to certain implementations.

FIG. 16B illustrates an example of a plot of calculated BX lifetimes vs. the extracted BX lifetimes from three QSs, according to certain implementations.

FIG. 16C illustrates an example of a plot of the average QY^{BX} from single dot AB statistics vs. the ensemble BX lifetimes, according to certain implementations.

FIG. 17A illustrates an example of a plot of the radial probability distributions for electron and hole wave functions in small-core, CdSbulk-CdSe—CdS quantum shells, according to certain implementations.

FIG. 17B illustrates an example of a plot of the radial probability distributions for electron and hole wave functions in medium-core, CdSbulk-CdSe—CdS quantum shells, according to certain implementations.

FIG. 17C illustrates an example of a plot of the radial probability distributions for electron and hole wave functions in large-core, CdSbulk-CdSe—CdS quantum shells, according to certain implementations.

FIG. 18 illustrates an example of a plot of the calculated Auger times as a function of the overall QS size and the CdS core size, according to certain implementations.

FIG. 19A illustrates an example of a plot of the PL as a function of excitation fluence for large core QSs, according to certain implementations.

FIG. 19B illustrates an example of a plot of the Integrated PL intensity vas a function of the fluence for large core QSs, according to certain implementations.

FIG. 20 illustrates an example of a schematic diagram of a system for measuring PI using a variable stripe length configuration, according to certain implementations.

FIG. 21 illustrates an example of a plot of the integrated PL (regular exciton PL subtracted) that is recorded using the variable stripe length configuration shown in FIG. 20, according to certain implementations.

FIG. 22A illustrates an example of a plot of the evolution of lasing in the microtube resonator at high powers, according to certain implementations.

FIG. 22B illustrates an example of a plot of the evolution of lasing in the microtube resonator at low powers, according to certain implementations.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

### I. Terminology

The phraseology and terminology employed herein are for the purpose of description and should not be regarded as limiting. For example, the use of a singular term, such as, “a” is not intended as limiting of the number of items. Also, the use of relational terms such as, but not limited to, “top,” “bottom,” “left,” “right,” “upper,” “lower,” “down,” “up,” and “side,” are used in the description for clarity in specific reference to the figures and are not intended to limit the scope of the presently disclosed technology or the appended claims. Further, it should be understood that any one of the features of the presently disclosed technology may be used separately or in combination with other features. Other systems, methods, features, and advantages of the presently disclosed technology will be, or become, apparent to one with skill in the art upon examination of the figures and the detailed description. It is intended that all such additional systems, methods, features, and advantages be included within this description, be within the scope of the presently disclosed technology, and be protected by the accompanying claims.

Further, as the presently disclosed technology is susceptible to embodiments of many different forms, it is intended that the present disclosure be considered as an example of the principles of the presently disclosed technology and not intended to limit the presently disclosed technology to the specific embodiments shown and described. Any one of the features of the presently disclosed technology may be used separately or in combination with any other feature. References to the terms “embodiment,” “embodiments,” and/or the like in the description mean that the feature and/or features being referred to are included in, at least, one aspect of the description. Separate references to the terms “embodiment,” “embodiments,” and/or the like in the description do not necessarily refer to the same embodiment and are also not mutually exclusive unless so stated and/or except as will be readily apparent to those skilled in the art from the description. For example, a feature, structure, process, step, action, or the like described in one embodiment may also be included in other embodiments but is not necessarily included. Thus, the presently disclosed technology may include a variety of combinations and/or integrations of the embodiments described herein. Additionally, all aspects of the present disclosure, as described herein, are not essential for its practice. Likewise, other systems, methods, features, and advantages of the presently disclosed technology will be, or become, apparent to one with skill in the art upon examination of the figures and the description. It is intended that all such additional systems, methods, features, and advantages be included within this description, be within the scope of the presently disclosed technology, and be encompassed by the claims.

Any term of degree such as, but not limited to, “substantially,” as used in the description and the appended claims, should be understood to include an exact, or a similar, but not exact configuration. For example, “a substantially planar surface” means having an exact planar surface or a similar, but not exact planar surface. Similarly, the terms “about” or “approximately,” as used in the description and the appended claims, should be understood to include the recited values or a value that is three times greater or one third of the recited values. For example, about 3 mm includes all values from 1 mm to 9 mm, and approximately 50 degrees includes all values from 16.6 degrees to 150 degrees.

The term “coupled” is defined as connected, whether directly or indirectly through intervening components, and is not necessarily limited to physical connections. The connection can be such that the objects are permanently connected or releasably connected. The terms “comprising,” “including” and “having” are used interchangeably in this disclosure. The terms “comprising,” “including” and “having” mean to include, but not necessarily be limited to the things so described. The term “real-time” or “real time” means substantially instantaneously.

Lastly, the terms “or” and “and/or,” as used herein, are to be interpreted as inclusive or meaning any one or any combination. Therefore, “A, B, or C” or “A, B, and/or C” mean any of the following: “A,” “B,” or “C”; “A and B”; “A and C”; “B and C”; “A, B and C.” An exception to this definition will occur only when a combination of elements, functions, steps, or acts are in some way inherently mutually exclusive.

### II. General Architecture

The systems disclosed herein improve upon previous techniques by embedding a quantum shells (QSs) in a perovskite host. The QSs provide improved electroluminescence by suppressing Auger recombination, and the emission wavelength can be tuned by changing the dimension(s) of the quantum-confined layer in the QSs. Further, the perovskite-QS blended films are suitable for light-emissive architectures in view of the observed multi-spectral electroluminescence (e.g., the QSs and perovskite can emit light at different wavelengths) with strong enhancement of the optoelectronics properties upon the addition of only a small amount of the QSs (e.g., about 5-15% wt). The apparent color of the emitted light can be tuned by changing the voltage applied across the active emissive layer. For example, as the voltage increases a greater percentage of the total light is emitted from the QSs compared to the perovskite, thereby shifting the apparent color towards the wavelength emitted by the QSs. Further, effective manipulation of (multi)excitons' overlap via core tuning in spherical quantum well geometry and high emission yields allow the QSs to be used as efficient lasers and light sources.

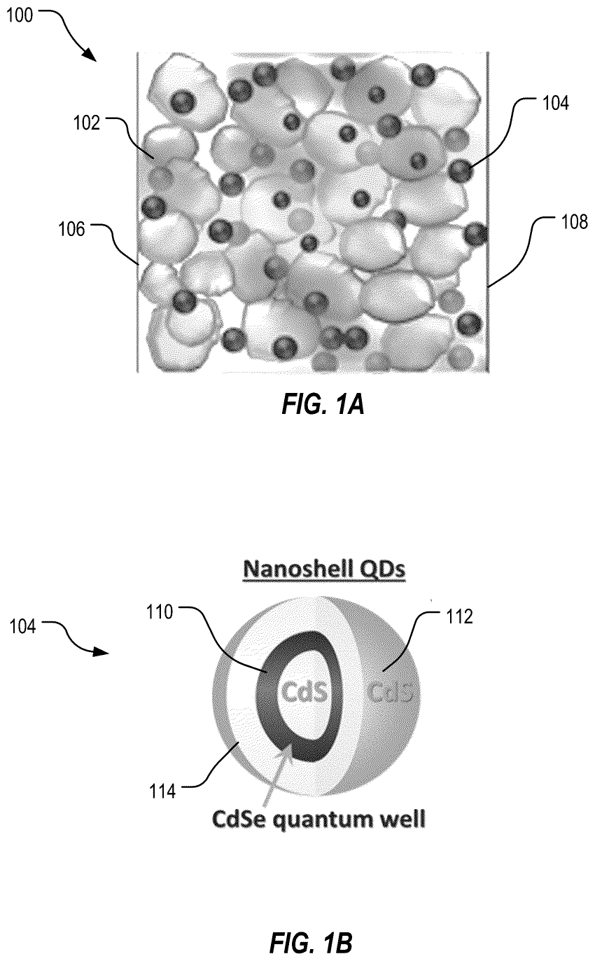

The systems and method disclosed herein provide light-emitting electrochemical cells with a conductive single-layer quantum shell (QS) and perovskite blend (QS-Pe blend). Light-emitting electrochemical cells utilize mobile ion redistribution to enhance charge injection and produce efficient emission from solution-processed, single-layer devices, making them particularly beneficial for applications with colloidal nanocrystals. The QS-Pe blend can include large-core QSs as a single-layer emissive component in the light-emitting electrochemical cell (LEC) geometry, as illustrated in FIG. 1A, which illustrates the LEC 100 having QSs 104 (e.g., the guest material) interspersed within a perovskite 102 (e.g., the host material).

The first conducting layer 106 is on a first side of the LEC 100, and the second conducting layer 108 is on the second side of the LEC 100. Running a current from the first conducting layer 106 to the second conducting layer 108 causes light to be emitted from the LEC 100. According to certain non-limiting examples, the light emitted from the perovskite can be in a different wavelength range than the light emitted by the QSs. For example, the light emitted by the perovskite can be centered around 500 nm, and the light emitted by the QSs can be centered around 650 nm.

FIG. 1B illustrates a non-limiting example of a QS. The QS can be a quasi-two-dimensional, spherical/spheroidal CQW nanoscale geometry that includes a substantially spherical/spheroidal shell (e.g., a first semiconductor) that is sandwiched between wider-bandgap semiconductor core and outer layers. In the example illustrate in FIG. 1B, the quantum-confined spherical shell is sandwiched between a CdS core and a CdS outer layer in a quantum shell (QS) geometry.

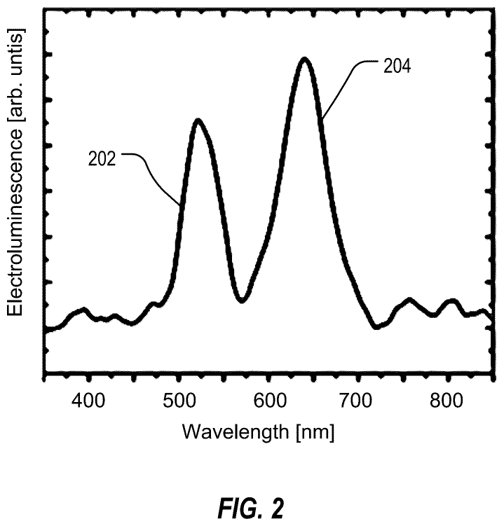

FIG. 2 illustrates a non-limiting example of a spectrum of the emitted light LEC 100. More particularly, FIG. 2 shows the electroluminescence in arbitrary units along the vertical axis and the wavelength in nm along the horizontal axis. The first emission peak 202 is light generated by the perovskite and the second emission peak 204 is light generated by the QSs. The center wavelengths of these peaks can be tuned. For example, the center wavelength of the first emission peak 202 can be tuned by changing the counterion of the perovskite. The center wavelength of the second emission peak 204 can be tuned, e.g., by changing the dimensions of the quantum-confined spherical shell and/or by selecting a different semiconductor for the quantum-confined spherical shell.

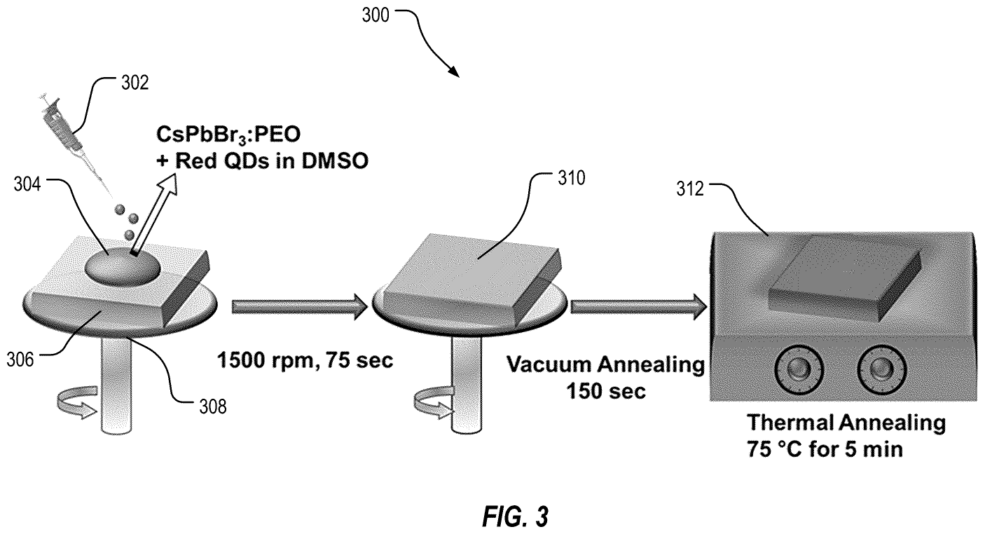

FIG. 3 illustrates a non-limiting example of a system 300 for forming the LEC 100 on a substrate 306. An injection device 302 applies a quantity of the liquid QS-Pe blend 304 to a conducting surface of the substrate 306. The substrate 306 is placed on a spin coating apparatus 308. The spin coating apparatus 308 spins at a predefined rate for a predefined period to obtain a film 310 of the liquid QS-Pe blend 304 having a uniform, predefined thickness. The film 310 is annealed using a heating device 312 to heat the substrate 306 for a predefined period.

According to certain non-limiting examples, the LEC 100 is formed on the substrate 306 using a CsPbBr₃ precursor solution to generate the final solution that is spin-coated to obtain an approximately 120 nm thick film on an indium tin oxide (ITO)-coated glass substrate. For example, the CsPbBr₃ precursor solution can be prepared by dissolving PbBr₂ (0.2 M) and CsBr (0.36 M) in dimethyl sulfoxide (DMSO). Polyethylene oxide (PEO) (10 mg/ml), which acted as a polyelectrolyte, and LiPF₆ (5 mg/ml), which acted as a salt with mobile ions, can be prepared in DMSO solution. The perovskite precursor solution can be prepared by mixing the CsPbBr₃, PEO, and LiPF₆ solutions in a 100:80:0.5 weight ratio. The final QS-Pe blend solution (CsPbBr₃+PEO+LiPF₆+ QSs) can be prepared by suspending colloidal QSs in DMSO at approximately 16 mg/ml and mixing 100 μL with 1315 μL of the precursor solution (CsPbBr₃+PEO+LiPF₆). This yielded a final weight ratio of 10 wt % QS:QS+CsPbBr₃.

The final solution can be stirred for 5 min with a vortex stirrer to achieve a uniform solution. The overall perovskite-QS LEC device architecture can be ITO/PEDOT:PSS/active layer/LiF/AI. The active layer can include CsPbBr₃, PEO, LiPF₆, and QSs.

The substrates can include pre-patterned indium tin oxide that can be cleaned in a sequence of non-ionic detergent wash, sonication in a deionized water bath with detergent for 20 min, sonication in deionized water only (repeated three times for 20 min each), and UV ozone treatment for 20 min. Aqueous poly(3,4-ethylenedioxythiophene):polystyrene sulfonate (PEDOT:PSS) solution (1.3-1.7%, Clevios AI 4083) can be filtered through a 0.45 μm GHP filter.

The PEDOT:PSS layer can be formed on the cleaned ITO-coated glass substrate by spin-coating the PEDOT:PSS solution on the ITO-coated glass substrate to obtain a film that is about 20 nm thick on the ITO-coated glass substrate. The film can be subsequently annealed at 150° C. for 20 minutes in a dry N₂-filled glovebox.

The active layer can be formed on the PEDOT:PSS layer by the prepared active layer precursor solution being spin-cast onto PEDOT:PSS at 1800 rpm for 60 s, followed by vacuum treatment for 90 s and thermal annealing at 75° C. for 5 min. For example, the active layer thicknesses can be about 120-130 nm.

To deposit the top electrode, samples can be transferred to a vacuum chamber, and a layer of LiF having a thickness of about 20 Å (angstroms) is deposited using a shadow mask. Next, in the vacuum chamber, a layer of Al having a thickness of about 800 Å is deposited using the shadow mask. For example, the shadow mask can be used to define twelve devices per substrate, each of the twelve devices having an area of about three mm².

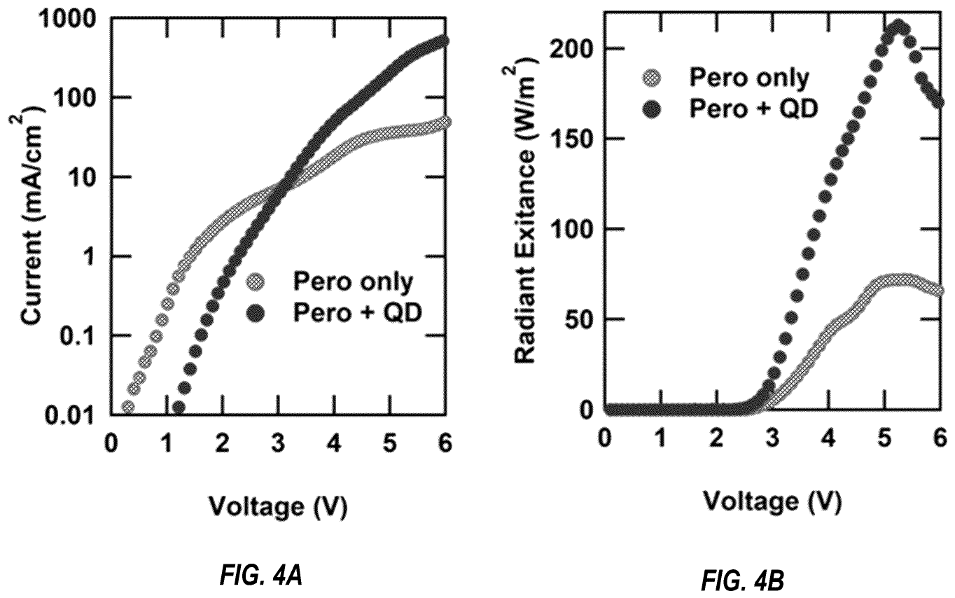

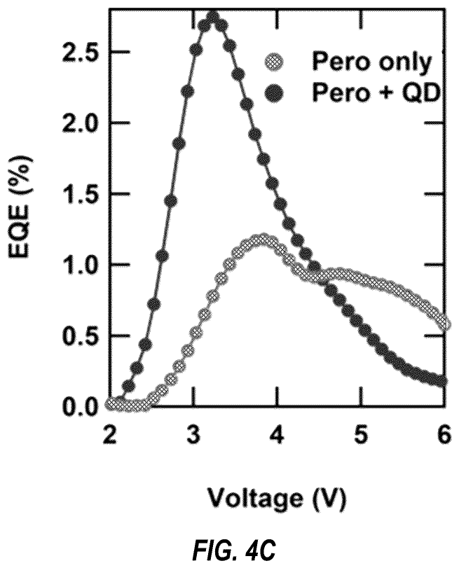

FIGS. 4A-4C illustrate measured data generated by applying a voltage across the LEC that is provided by the above-described method. In each of these figures, data was measured for two different preparations of the active layer: a first preparation with perovskite only (i.e., no QS), which is labeled as “Pero only” and a second preparation with QSs embedded in the perovskite, which is labeled as “Pero+QD.”

FIG. 4A illustrates a plot of the current (vertical axis) passing through the LEC as a function of the applied voltage (horizontal axis). FIG. 4B illustrates a plot of the radiant exitance (vertical axis) from the LEC as a function of the applied voltage (horizontal axis). FIG. 4C illustrates a plot of the external quantum efficiency (EQE) of the LEC as a function of the applied voltage.

According to certain non-limiting examples, the active layer in the LEC 100 is fabricated by using oleic acid passivating ligands on surfaces of the QSs, the oleic acid passivating ligands can be exchanged with 3-mercaptopropionic acid (MPA) to facilitate charge injection in a solid-state form. Although oxide matrices, such as ZnMgO can be used as the electric transport layer in colloidal semiconductor quantum wells (CQW) devices, an alternative approach is beneficially used for the electric transport layer. The alternative approach takes advantage of CsPbBr₃ perovskite-based injection layer offering both excellent emissive and efficient charge transport properties. The use of CsPbBr₃/QS blends allows combining complementary properties of both material classes, which leads to dual emission colors (e.g., perovskite emits green light and the QSs emit red light) and efficient charge injection. For example, the QSs can be effectively populated and exhibit bright electroluminescence. Notably, the contribution of QS into EQE surpasses that of the CsPbBr₃ perovskite layer. Similarly, all other relevant optoelectronic parameters (injection current, radiant exitance) improve upon the addition of about 10 wt % of the luminescent QSs. as illustrated in FIGS. 4A-4C.

According to certain non-limiting examples, the LEC 100 embeds QSs in perovskite to provide perovskite-QS blended films that are operable for light-emissive architectures (e.g., emitting green/red electroluminescence) with strong enhancement of the optoelectronics properties upon the addition of only a small amount of highly emissive quantum shells. Beneficially, effective manipulation of (multi)excitons' overlap via core tuning in spherical quantum well geometry and high emission yields allow the use of these nanoparticles as efficient lasers and light sources.

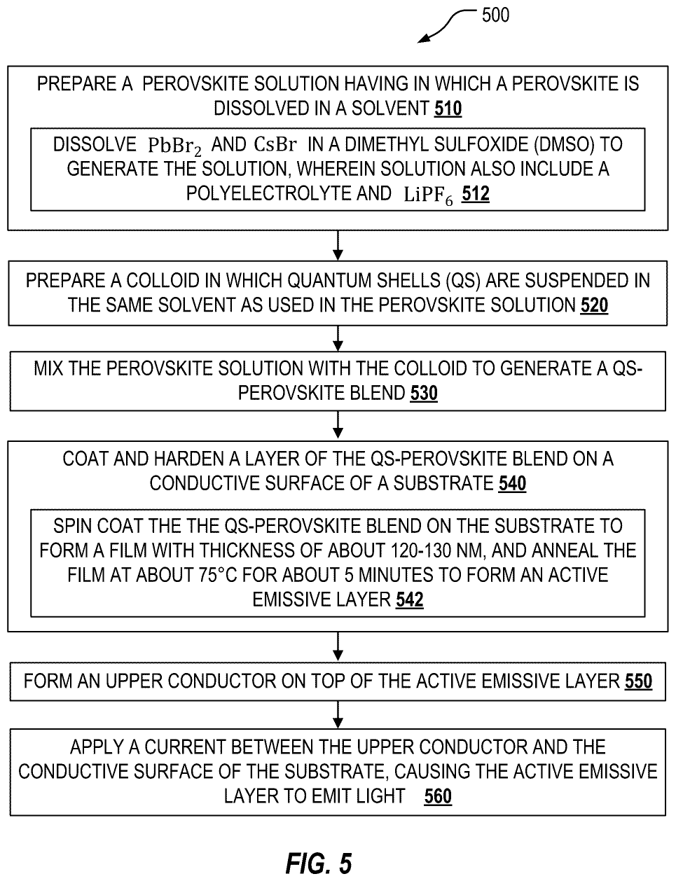

FIG. 5 illustrates an example of method 500 for fabricating an electroluminescent device or an LEC. Although the example routine depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

According to some examples, in step 510, the method includes preparing a perovskite solution in which a perovskite is dissolved in a solvent. Step 510 can optionally include step 512. In step 512, a CsPbBr₃ precursor solution is prepared by dissolving PbBr₂ and CsBr in a dimethyl sulfoxide (DMSO) to generate the precursor solution, wherein the precursor solution also includes a polyelectrolyte and LiPF₆. Step 510 can be performed in accordance with the above-described method for preparing the perovskite precursor solution.

According to some examples, in step 520, a colloid is prepared in which quantum shells (QS) are suspended in the same solvent as used in the perovskite solution.

According to some examples, in step 530, the method includes mixing the perovskite solution with the colloid to generate a QS-perovskite blend. Step 530 can be performed in accordance with the above-described method for the final solution having a final weight ratio of 10 wt % QS:QS+CsPbBr₃.

According to some examples, in step 540, the method includes coating and hardening a layer of the QS-perovskite blend on a conductive surface of a substrate. Step 540 can optionally include step 542. In step 542, the method includes the QS-perovskite blend is spin coated on the substrate to form a film with a thickness of about 120-130 nm. The film is then annealed at about 75° C. for about 5 minutes to form an active emissive layer. Steps 540 and 542 can be performed in accordance with the above-described method for forming the active layer on the ITO substrate.

According to some examples, in step 550, the method includes forming an upper conductor on top of the active emissive layer. Step 550 can be performed in accordance with the above-described method for forming the top electrode.

According to some examples, in step 560, the method includes applying a current between the upper conductor and the conductive surface of the substrate, causing the active emissive layer to emit light.

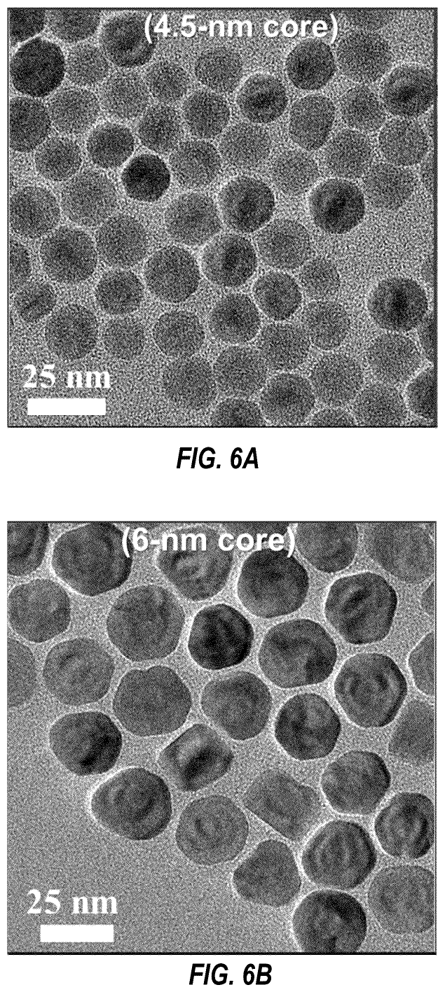

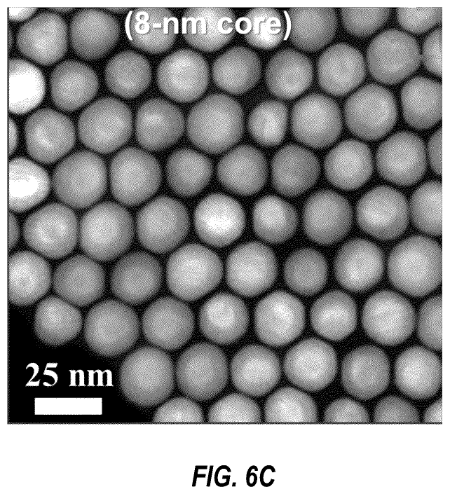

FIGS. 6A-6C illustrate TEM images of the individual quantum shells (QSs) with different core sizes. The Figures shows the geometry of the core/shell structure for CdS/CdSe/CdS QS with three different core size diameters (referred to as “small”, D=4.5 nm), “medium” (D=6 nm), and “large” (D=8.2 nm). In FIGS. 6A-6C, the QSs are prepared using the colloidal epitaxy approach. FIG. 6A illustrates a TEM image of the individual QSs having a core size diameter of D=4.5 nm. FIG. 6B illustrates a TEM image of the individual QSs having a core size diameter of D=6 nm. FIG. 6C illustrates a TEM image of the individual QSs having a core size diameter of D=8 nm.

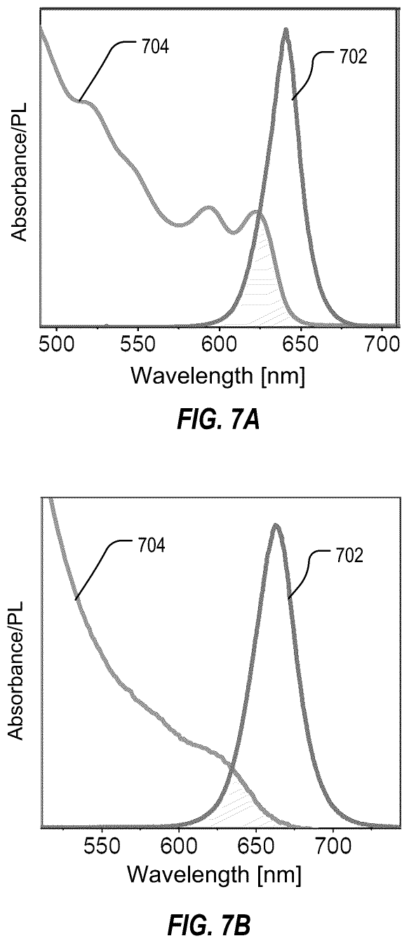

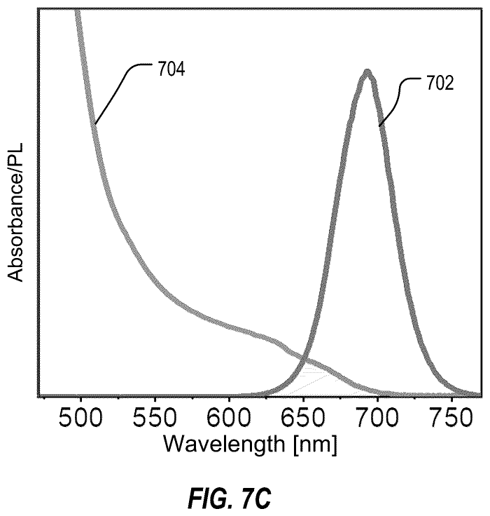

FIGS. 7A-7C illustrate absorption and photoluminescence (PL) plots for the small, medium, and large QSs shown in FIGS. 6A-6C. The ensemble measurements of PL 702 and absorption 704 data of the three QS types are shown in FIG. 7A for the small QS ensemble, in FIG. 7B for the medium QS ensemble, and in FIG. 7C for the large QS ensemble. The PL linewidths of all three samples (e.g., linewidths ranging between 69-105 meV) are comparable to those of high-quality CdSe/CdS core-shell QDs, suggesting a relatively low dispersion of the CdSe layer thickness. The presence of the CdSe quantum-well layer in QS is evidenced by the color contrast in the TEM images of the 8-nm-core samples shown in FIG. 6C.

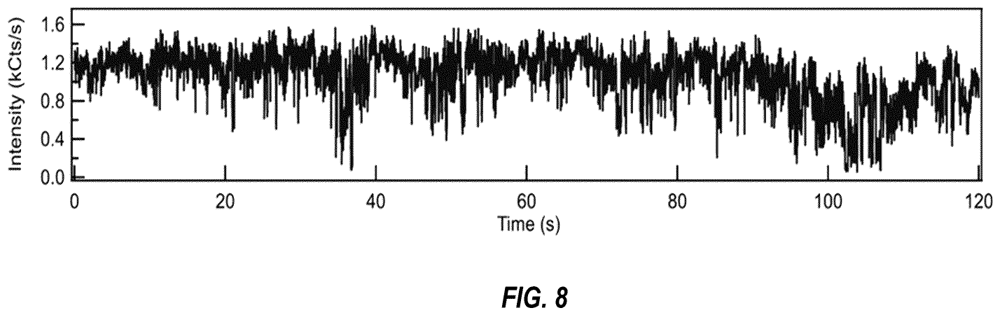

Various spectroscopic measurements on the QSs are illustrated in FIGS. 8-12. For single dot spectroscopy, low-concentration QS solutions are dispersed on quartz slides with surface density <0.01 μm². The sample is mounted on a translation stage of the microscope; individually located QSs are excited by 405 nm, 50 ps laser pulses through a high-NA (numerical aperture) oil immersion objective that is also used to collect PL signal. The emitted light is sent to a pair of single-photon detectors (avalanche photodiodes) positioned in two arms of the Hanbury-Brown-Twiss correlation scheme. Time-correlated, time-stamped single-photon counting is performed on board of MULTIHARP correlation card. The average number of excitons N per CdS/CdSe/CdS QS was computed using the well-known expression N=jσ, where j is the number of incident photons per cm² per pulse, and a is the absorption cross-section of an individual QS.

The QS geometry has the benefit of reducing the Auger recombination, which in turn leads to changes in the blinking traces, from the common “ON/OFF” behavior to the appearance of multiple intensity levels, corresponding to the emission signatures of various excitonic complexes. FIGS. 8-12 show the PL time trajectories (blinking traces), lifetimes, and second-order correlation g²(t) functions (antibunching trace, AB) for a large (D=8.2 nm) core CdSe/CdS/CdSe QS nanocrystal that exhibits high BX emission yield. Similar blinking behaviors for small and medium core nanocrystals with lower QY^{BX} has also been observed, as disclosed in A. Marder et al., “CdS/CdSe/CdS Spherical Quantum Wells with Near-Unity Biexciton Quantum Yield for Light-Emitting Device Applications,” ACS Materials Lett., Vol. 5, pp. 1411-1419 (2023), which hereby incorporated by reference in its entirety.

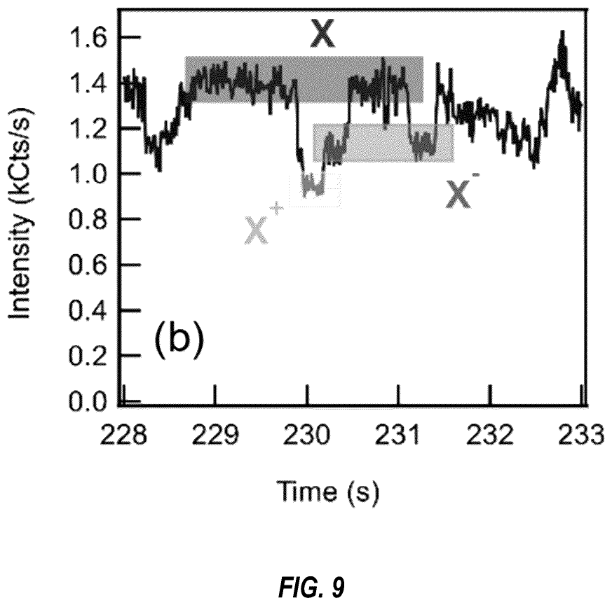

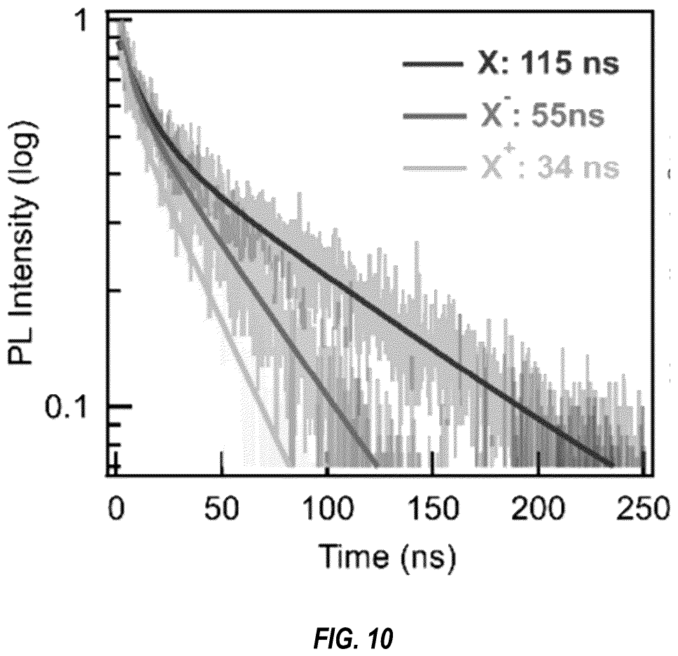

The QS exhibits at least three distinctive emission levels that are assigned to neutral exciton (X) and negatively/positively charged (X⁻/X⁺) excitons (trions), as shown in FIG. 9, for example. The highest PL intensity level in such a well-defined blinking trace can arise from single-X emission with 100% emission yield. Lower intensity PL emission levels have correspondingly shorter lifetimes, affected by progressive contributions of non-radiative relaxation channels such as Auger and trapping decays. Therefore, the appearance of single exponential decay for the highest PL intensity level with a lifetime that is the same or even longer than the average PL lifetime of the bulk solutions is indicative of the fully “ON” state with near-unity quantum yield. The PL lifetime shown in FIG. 10 includes a long component corresponding to τₓ=115 ns, longer than that of the bulk solution.

The ordering of the exciton states is dictated by the degree of the Auger recombination, with elemental Auger rates in colloidal NQDs for negative trions (k_{A}^{X}^{^{−}}) being generally smaller than for the positive ones (k_{A}^{X}^{⁺}) due to the more pronounced hole's localization and greater density of the valence band states. According to previous works, biexcitonic Auger rate is described by the superposition principle, k_{A}^{BX}=2(k_{A}^{X}^{^{−}}+k_{A}^{X}^{⁺}), where radiative times of the higher order excitons scale with the neutral exciton's rate as τᵣ^{X}/τᵣ^{MX}=β, wherein β is the channel's overlap factor).

While the above analysis of the blinking intensity levels provides detailed information about lifetimes and quantum yields of individual species, it depends on the appearance of well-defined blinking traces with seconds-long uninterrupted emissions from each of the excitonic states. Alternatively, the many blinking traces are represented as a “flickering” type of behavior in which the emission rapidly (e.g., on a sub-100 ms scale) switches between various emissive states (ON and GREY states), preventing the detailed analysis, especially for multiexciton states. However, an independent measurement of QY^{BX} is possible via second-order correlation, e.g., the g²(τ) function. The ratio between the center peak (at τ=0) and the side peaks of the g²(τ) trace corresponds to the photon antibunching effect, indicating the probability of simultaneously detecting two photons within one excitation cycle. Apart from background influence and detector crosstalk, both of which can be nearly zero in the experiments, the recorded non-zero probability indicates one of the two options. First is the possibility of clustering, resulting in simultaneous excitation of several quantum emitters. The statistical approach indicates that the normalized value of the central peak is given by g²(0)=1−1/M, where M is the number of independent emitters.

Values above 0.5 may indicate emission from several QSs within the excitation spot. The second possibility is a quantum cascade emission of multiple photons from a single QS, specifically a biexciton-exciton cascade. In such cases, g²(0)=QY^{BX}/QY^{X} in the limit of the weak pump (N<<1). Given the above regarding near-unity QY^{X} in highly emissive individual dots, the AB method allows the determination of the absolute values of the biexciton QY. Although the nanocrystal clustering in organic solvents is usually not observed, a time-gating technique can be applied to AB measurements to separate these two possibilities. By post-processing the TCSPC photon collection events, the time gate (TG) is progressively set at intervals that exceed the biexciton lifetime, thus excluding its contribution to the g²(τ) curve that is now defined only by exciton emission events. Accordingly, gating does not affect the central peak value if the emission events come from multiple uncorrelated emitters.

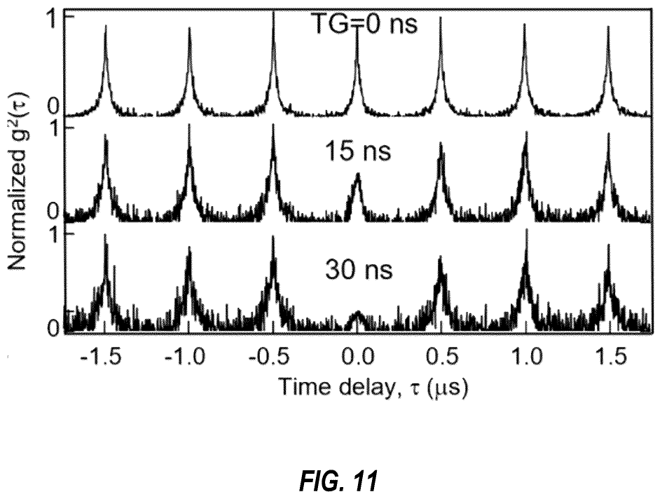

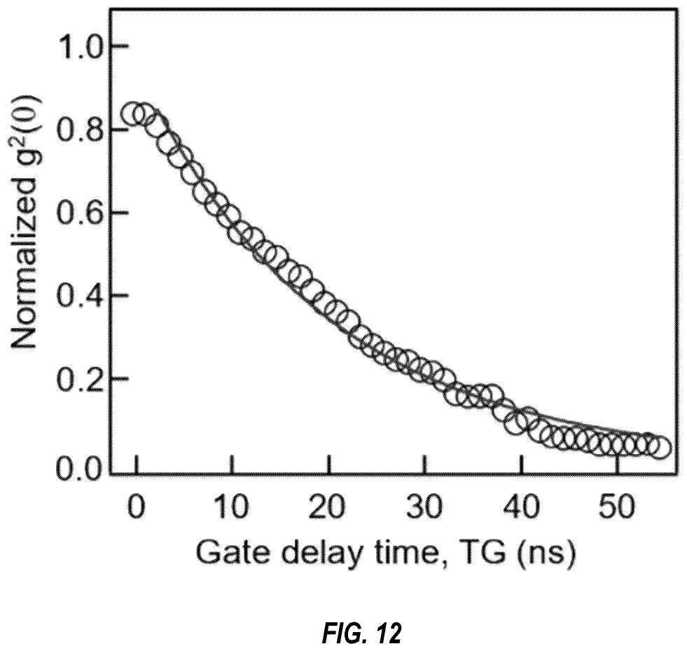

FIG. 11 illustrates this approach, indicating that initial AB value decreases from g²(0)=0.82 at TG=0 ns (no gating) to g²(0) is about 0.5 at TG=15 ns and g²(0) is about 0.2 at TG=30 ns. All AB data can be recorded at an average excitation value of N˜0.25. The detailed dependence of the g2(0) value as a function of the applied gate time is illustrated in FIG. 12). It is seen to quickly approach zero, with fitted exponential decay time resembling the BX lifetime (τ is about 20 ns), confirming that the emission is from a single QS and the central peak value g²(0)=QY^{BX}.

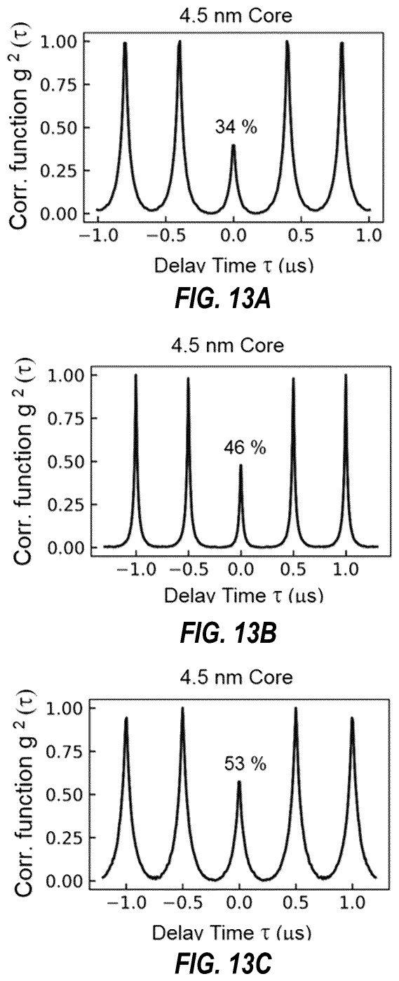

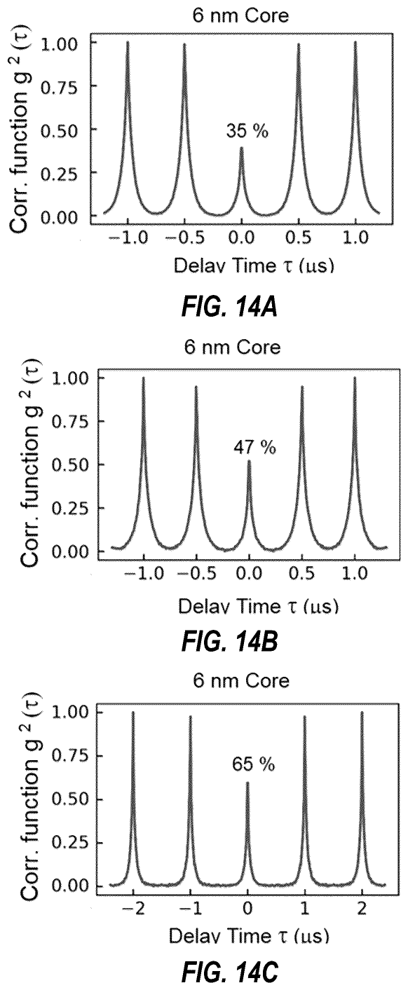

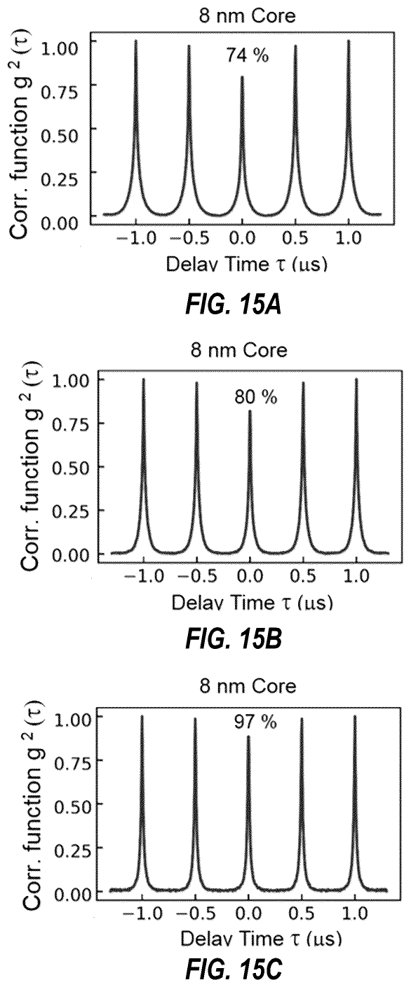

FIGS. 13A-C, illustrate examples of g²(τ) functions for small core CdS/CdSe/CdS QSs. FIGS. 14A-C, illustrate examples of g²(τ) functions for medium core CdS/CdSe/CdS QSs. FIGS. 15A-C, illustrate examples of g²(τ) functions for large core CdS/CdSe/CdS QSs. FIGS. 13A, 14A, and 15A belong to the first quartile of AB values. FIGS. 13B, 14B, and 15B belong to the median quartile of AB values. FIGS. 13C, 14C, and 15C belong to the third quartile of AB values. In each of these plots, the number on the panel indicates the QY^{BX} as computed from the ratio of the central to side peak areas.

The blinking measurements are obtained using a concentrated solution of QSs in hexane is diluted and dispersed onto a glass substrate with an approximate surface density of less than 0.01 per μm². The sample is mounted on a translation stage of an optical microscope and excited with 405 nm, 50 ps pulses through a 100×, 1.2 NA (numerical aperture) oil-immersion objective that is also used to collect PL. The laser frequency is set so that the time between pulses is much longer than the PL decay times to ensure complete relaxation of excitons between sequential laser pulses, around 1-2 MHz. The PL signal is sent to a pair of avalanche photodiodes that are positioned at two arms of the standard Hanbury-Brown-Twiss arrangement with a 50/50 beam splitter. Time-tagged time-correlated single-photon counting (TCSPC) is performed using PICOQUANT MULTIHARP 150 electronics. TCSPC simultaneously records photon arrival times with respect to the beginning of the measurement cycle and the excitation laser pulse. Hence, it allows us to compile PL decay curves for any particular time segment of the PL intensity trajectory or a chosen window of the intensity distribution function. Homemade IGOR software has been used to read data streams from each channel and compile gated g²(τ) functions at any TG value for biexciton quantum yield determination.

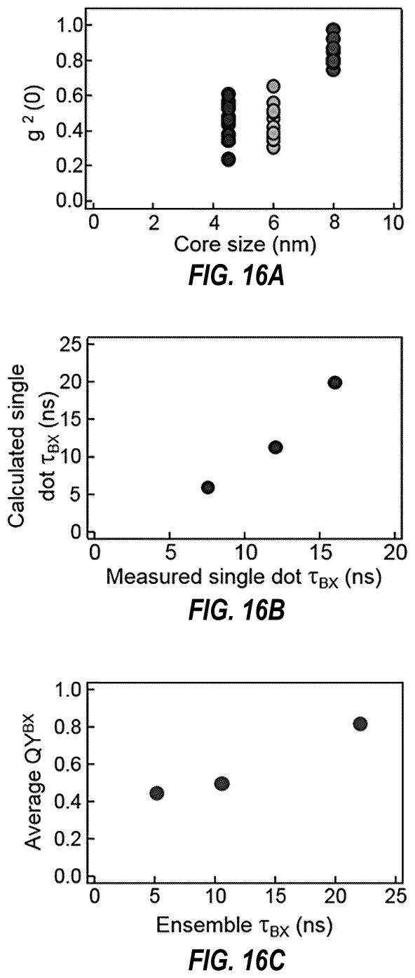

FIG. 16A illustrates the statistics of g²(0) values for all QSs (i.e., small, medium, and large cores). FIG. 16B illustrates the Calculated BX lifetimes vs. the extracted BX lifetimes from three single dots as discussed herein. FIG. 16C illustrates the average QY^{BX} from single dot AB statistics vs. the ensemble BX lifetimes. All data was acquired in the power regime of average N=0.25-0.5 eh pairs.

These Figures present examples of g²(τ) functions and distributions of QY^{BX} values for the three samples. As seen, the small core sample shows the lowest values, with the average QY^{BX}˜45% and first and third quartiles spanning QY^{BX}˜30-55% range. The medium core sample shows a similar average QY^{BX}˜50% and 40-60% range. However, the large core sample shows a much higher average QY^{BX}˜82%, with the third quartile reaching the 90% range, while several individual QS have shown, within the measurements error, even QY^{BX}˜100%. The distribution plot in FIG. 16A demonstrates that QY^{BX} values are correlated with the size of the QS's core. Further, FIGS. 16B-C show that measured and calculated τ_{BX} also correlates with quantum yield as expected via a relationship:

$$\\ {τ}_{BX} = {\frac{{QY}^{{}_{} {}_{} BX}}{k}}_{rad}^{BX} = \frac{{QY}^{{}_{} {}_{} BX} {τ}_{r}^{{}_{} X}}{β} .$$

The smaller variance of QY^{BX} values for large core QSs indicates better particle-to-particle homogeneity as attributed to changes in k_{rad}^{BX} or k_{A}^{BX}.

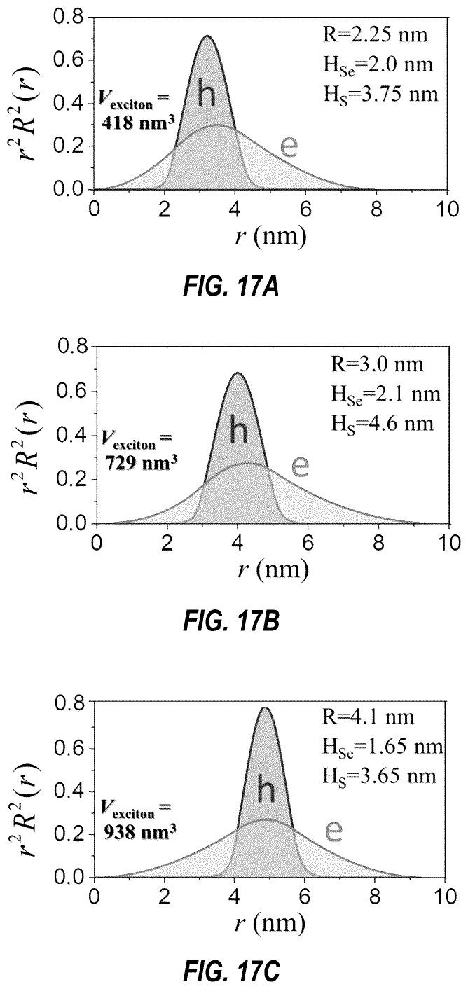

FIGS. 17A-C illustrate calculated electron and hole radial probabilities in the effective mass approximation model for three samples discussed above. Notably, both the thickness of the CdSe quantum well layer and the overlap of electron and hole wave functions are similar among the three samples. Hence, the defining factor affecting Auger recombination rates is the effective exciton volume, which is substantially larger for larger core QSs.

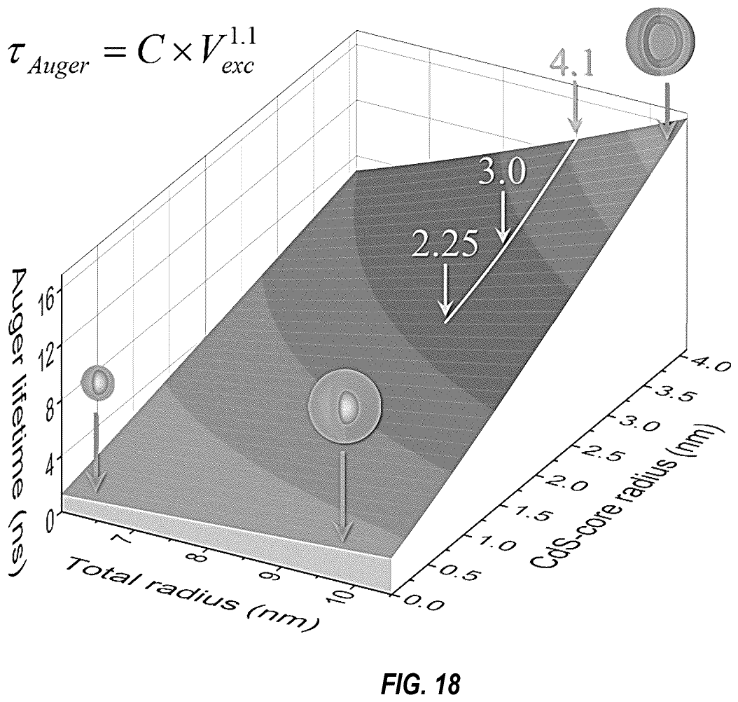

FIG. 18 shows calculated BX Auger lifetimes as predicted by the scaling model for QSs with different radii. Here, the effect of QS geometry on Auger lifetimes was estimated by assuming a superlinear scaling of τ_{Auger} with the excitons volume τ_{Auger} is about V^{1.1}. Such volume scaling is based on the interacting formalism that accurately describes Coulomb coupling between the initial and final multi-charge states in large-size nanostructures and, therefore, applies to the quantum shell geometry. According to theory, Auger lifetimes more than double for large core samples vs. the small core ones, in agreement with the observed enhancement of measured BX lifetimes and corroborating much higher QY^{BX} of the large core samples. Notably, the theoretical ratio of BX lifetimes for 8-nm-core and 4.5-nm-core samples is BX_{τ8-nm}/BX_{τ4.5-nm}≈2.2, which approximately agrees with the single-particle measurements of BX_{τ8-nm}/BX_{τ4.5-nm}≈3.

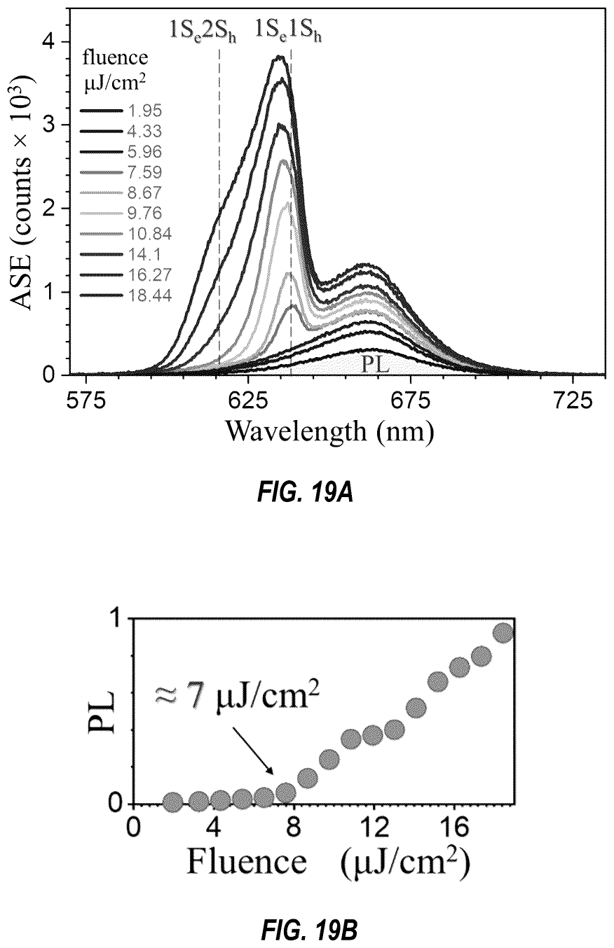

An efficient BX emission in QSs advantageously enables using these nanostructures for light-emitting applications. For example, amplified spontaneous emission (ASE) can be realized using QSs. FIGS. 19A-22B illustrate measured ASE and modal gain in large-core QSs,

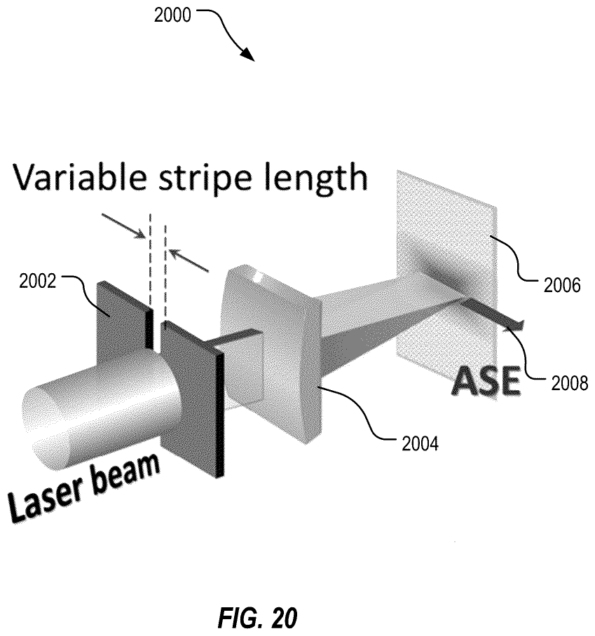

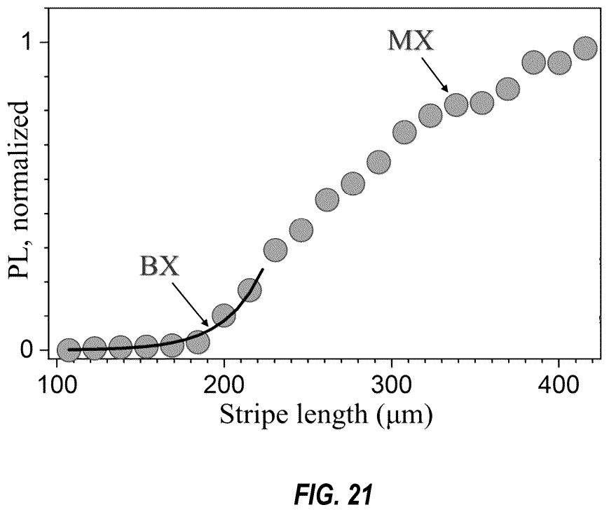

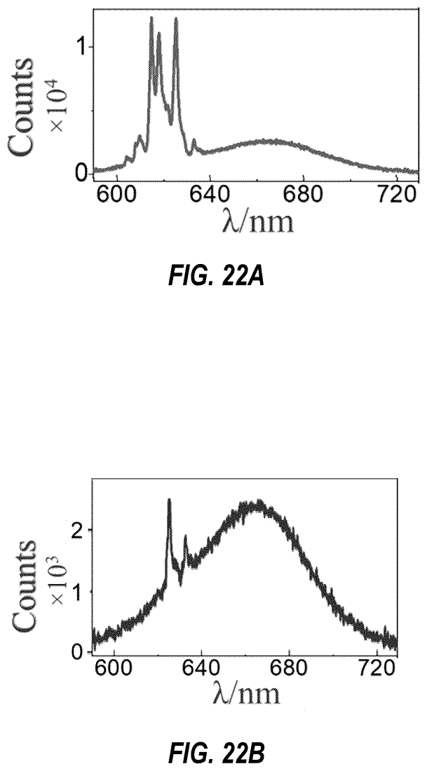

FIG. 19A illustrates PL as a function of excitation fluence for large core QSs. FIG. 19B illustrates the integrated PL intensity vs. fluence, and thereby revealing the ASE threshold. FIG. 21 illustrates the integrated PL (e.g., regular exciton PL subtracted) recorded using variable stripe length configuration, using the measurement system shown schematically in FIG. 20. In FIG. 21, the solid black curve is a fit to the modal gain equation as described herein. FIGS. 22A-22B illustrate the evolution of lasing in the microtube resonator at low and high powers.

As shown in FIG. 19A, the onset of ASE can be observed at 637 nm, corresponding to BX transition at the threshold fluence of F is about 7 μJ/cm². This value is reduced compared to the threshold observed for small core QSs, highlighting the importance of high QY^{BX}. Upon further increase of the excitation fluence, the saturation of BX emission and the emergence of an even higher energy ASE is observed at about 615 nm, likely corresponding to (multi)exciton emission at 1Sₑ-2Sₕ interband transition. Such large spectral bandwidth and low excitation threshold points toward large gain values inherent to these materials. For example, FIG. 21 shows integrated emission intensity (regular PL emission from X peak is subtracted) as a function of variable stripe length l of the excitation profile and exhibits superlinear growth at the threshold length lₜₕ˜200 μm. To derive the magnitude of the modal (i.e., net) gain g, this dependence is analyzed using a commonly employed expression of the intensity vs. stripe length,

$$\\ {I}_{PL} = A * ( exp ( gl ) - 1 ) / g ,$$

where A is a constant proportional to the spontaneous emission power density of biexcitons. This dependence fits the initial exponential rise (it does not account for the saturation region) and yields modal gain value g is about 450 cm⁻¹, providing the first quantitative measure of the optical amplification in quantum shells. Moreover, after the saturation of the BX emission (at F of about 11 μJ/cm² and l˜300 μm), an appearance of the second “threshold” is observed at F of about 14 μJ/cm². This feature corresponds to the broadening of the ASE to about 615 nm range with the involvement of multiexcitonic complexes at 1Sₑ-2Sₕ interband transitions, doubling the ASE threshold value due to the degeneracy of the hole states.

To further explore the MX characteristics of QSs, an optical resonator was constructed by incorporating QSs inside a thin glass microcapillary tube (inner tube diameter of about 100 m). Upon optical excitation, the resonator tube produced sharp lasing modes, first at the BX transition and then followed by higher energy MX transitions at the increased pump fluence, as shown in FIGS. 22A-22B. The spectral profile of high-power stimulated emission is unusual, as it appears to include high-energy multiexciton transitions that typically do not contribute to lasing in 0 D-2D nanocrystals. This is because such MX states are short lived in strongly confined nanocrystals. In the case of QSs, the survival of high-energy MX modes in the lasing cavity provides clear evidence of the suppressed Auger decay involving these MX states.

FIGS. 19A-22B used thin-film samples of nanocrystals that can be prepared for measurements by first performing an additional anti-solvent precipitation with ethanol, then re-dispersing the samples in 9:1 hexane:octane. The concentrated solutions can be spin-cast onto quartz microscope slides. To excite the sample 2006, a 1 kHz, 150 fs amplified Ti: sapphire laser was frequency doubled to 400 nm, and the beam was focused on the sample as a stripe with a 30 mm cylindrical lens 2004, with the length of the stripe I controlled by the micrometer adjusted slit 2002 placed immediately before the lens 2004. An optical fiber collected the emission 2008 from the edge of the stripe (perpendicular to the excitation's beam direction) and fiber-coupled to a portable spectrometer. For microring lasing experiments, the concentrated QS solution was drawn in a thin quartz microcapillary tube with a 100 μm inner diameter and allowed to evaporate, forming a thin film. The same excitation arrangement was used; however, the excitation power was considerably higher due to difficulties focusing the light into a cylindrical tube.

While the present disclosure has been described with reference to various implementations, it will be understood that these implementations are illustrative and that the scope of the present disclosure is not limited to them. Many variations, modifications, additions, and improvements are possible. More generally, implementations in accordance with the present disclosure have been described in the context of particular implementations. Functionality may be separated or combined differently in various implementations of the disclosure or described with different terminology. These and other variations, modifications, additions, and improvements may fall within the scope of the disclosure as defined in the claims that follow.

What is claimed is:

1. An active emissive layer configured for use in an electroluminescent device, the active emissive layer comprising:
a host-guest blend having:
a host with a perovskite, and
a guest with quantum shells embedded in the host.

2. The active emissive layer of claim 1,
wherein,
the electroluminescent device is a light-emitting electrochemical cell; and
the host-guest blend includes colloidal nanocrystals.

3. The active emissive layer of claim 1,
wherein,
the host is soluble in a same solvent that is used as a solution of the guest.

4. The active emissive layer of claim 1,
wherein,
the quantum shells include a quantum-confined, spheroidal shell having a first semiconductor that is sandwiched between a core and an outer layer, and
the core and the outer layer include a second semiconductor having a wider band gap than the first semiconductor.

5. The active emissive layer of claim 4,
wherein,
the quantum shells are sized to suppress multi-exciton Auger recombination.

6. The active emissive layer of claim 4,
wherein,
the first semiconductor includes CdSe,
the core includes a second semiconductor,
the second semiconductor includes CdS, and
the outer layer includes the second semiconductor.

7. The active emissive layer of claim 4,
wherein,
the cores of the quantum shells have a diameter that is in a range of about 4 nanometers to about 10 nanometers.

8. The active emissive layer of claim 1,
wherein,
the host is operable to emit light in a first wavelength range when an electrical current is applied through the host, and
the guest is operable to emit light in a second wavelength range when the electrical current is applied through the guest.

9. The active emissive layer of claim 8,
wherein,
the first wavelength range depends on a counterion of the perovskite, and
the second wavelength range depends on (i) dimensions of a quantum well in the quantum shells, and (ii) a semiconductor material of the quantum well.

10. The active emissive layer of claim 1,
wherein,
a mass ratio of the quantum shells to the perovskite is in a range of about 5% to about 15%.

11. The active emissive layer of claim 1,
wherein,
the perovskite has a molecular structure that includes a monovalent cation labeled “A”, a divalent cation labeled “B”, and a monovalent anion labeled “X”; and
the molecular structure is represented by ABX₃.

12. The active emissive layer of claim 1,
wherein,
the perovskite is CsPbBr₃, CsPbCl₃, and/or CsPbI₃.

13. The active emissive layer of claim 1,
wherein,
the active emissive layer is operable to tune an apparent color of light emitted from the active emissive layer by changing a current to flow through the active emissive layer and/or by changing of voltage applied across the active emissive layer that causes a current to flow through the active emissive layer.

14. The active emissive layer of claim 1,
wherein,
the quantum shells include first shells having first quantum wells of a first diameter, the first quantum wells include quantum-confined, spheroidal shell,
the quantum shells include second shells having second quantum wells of a second diameter that is larger than the first diameter, and
the first shells are operable to emit light in a different wavelength range than the second shells.

15. A method to fabricate an active emissive layer configured for use in a light-emitting electrochemical cell (LEC), the method comprising:
preparing a solution with a perovskite in a first solvent to form a perovskite solution;
preparing a colloid with quantum shells suspended in a second solvent, the second solvent and the first solvent being a same solvent;
mixing the perovskite solution with the colloid to generate a blended mixture;
providing the active emissive layer of the mixture on a substrate, and
removing the first solvent to solidify the active emissive layer, the conductive surface being on a first side of the active emissive layer.

16. The method of claim 15,
wherein,
the substrate has a conductive surface including a first electrode and a second electrode, and
the method further includes applying a voltage between the first electrode and the second electrode thereby causing a current through the active emissive layer, and
the current causes light to be emitted from the active emissive layer.

17. The method of claim 15, further comprising:
providing a first conductor on the substrate on a first side of the active emissive layer;
providing a conductor on a second side of the active emissive layer; and
applying a voltage between the conductive surface conductor on the second side causing a current through the active emissive layer, the current causing light to be emitted from the active emissive layer.

18. The method of claim 15,
wherein,
the providing of the active emissive layer of the mixture on the substrate includes:
spin coating the mixture on the substrate to form a film having a thickness in a range of about 40 nanometers to about 400 nanometers, and
annealing the film at a temperature in a range of about 60° C. to about 90° C. for a period of about 2 minutes to about 10 minutes to form the active emissive layer.

19. The method of claim 15,
wherein,
the preparing of the solution with the perovskite in the first solvent includes dissolving PbBr₂ and CsBr in a dimethyl sulfoxide (DMSO) to generate the solution,
the solution includes a polyelectrolyte and LiPF₆,
the preparing of the colloid includes suspending the quantum shells in the DMSO solvent, and
the quantum shells include spheroidal shell with CdSe sandwiched between a core and an outer layer respectively comprising CdS.

20. The method of claim 15,
wherein,
the polyelectrolyte includes polyethylene oxide (PEO),
the solution is prepared such that CsPbBr₃, PEO, and LiPF₆ are mixed in about a 100:80:0.5 weight ratio, and
the blended mixture has a weight ratio for QS:QS+CsPbBr₃ in a range of about 5 wt % to about 15 wt %.
